(19) United States
(12) Patent Application Publication
(10) Pub. No.: US 2024/0006436 A1
(43) Pub. Date: Jan. 4, 2024

(54) IMAGE SENSOR AND METHOD OF MANUFACTURING AN IMAGE SENSOR

(71) Applicant: ams Sensors USA Inc., Plano, TX (US)

(72) Inventors: Muhammad Maksudur RAHMAN, Fremont, CA (US); Ananth TAMMA, Boise, ID (US); Stefano GUERRIERI, Kessel-Lo (BE)

(73) Assignee: ams Sensors USA Inc., Plano, TX (US)

(21) Appl. No.: 17/852,676

(22) Filed: Jun. 29, 2022

(51) Int. Cl. H01L 27/146

(52) U.S. Cl. CPC H01L 27/14621; H01L 27/1469; H01L 27/14634; H01L 27/14643

(57) ABSTRACT

An image sensor, comprises a three-dimensional integrated circuit comprising a stack with at least a top-, a middle-, and a bottom-tier. The bottom-tier (BTR) comprises a first array of photodetectors, denoted first pixels (PD1), and the first pixels being sensitive in the visual and/or near-infrared spectral range. The middle-tier (MTR) comprises a second array of photodetectors, denoted second pixels (PD2), and the second pixels being sensitive in the short-wave infrared spectral range. The top-tier (TTR) comprises an application-specific integrated circuit, denoted ASIC, operable to read out the arrays of the first and second photodiodes (PD1, PD2).

This disclosure relates to an image sensor and to a method of manufacturing an image sensor. Furthermore, this disclosure relates to an electronic device comprising the image sensor.

### BACKGROUND OF THE DISCLOSURE

Simultaneous imaging of visual (VIS), near-infrared (NIR) and short-wave infrared (SWIR) spectral ranges using the same device (i.e., using same footprint, and readout circuitry) and using same optical path/optical axis can be very valuable to many applications such as artificial and virtual reality, AR/VR, consumer, health, security, robotics applications, etc. The art has come up with image sensors where visible and NIR pixels are implemented in cells in a side by side manner and, thus, require large area. These devices typically are not possible to scale down. To date there is no existing single pixel which combines all of the key features of simultaneous imaging together into one compact image sensor, which uses same footprint, and readout circuitry.

It is an object of the present disclosure to provide an imaging sensor, an electronic device and a method for manufacturing an imaging sensor which allows for imaging of visual (VIS) and/or near-infrared (NIR) as well as short-wave infrared (SWIR) spectral ranges using the same device.

These objectives are achieved by the subject-matter of the independent claims. Further developments and embodiments are described in the dependent claims.

### SUMMARY OF THE DISCLOSURE

The following relates to an improved concept in the field of imaging sensors. One aspect relates to an SWIR sensitive sub-pixel which is stacked on a VIS light sensitive sub-pixel to form a single pixel. A shared readout circuitry, e.g., an ASIC, can read out images in the visual (VIS) and short-wave infrared (SWIR) spectral ranges separately or together. For example, the proposed concept employs back-side illumination, BSI, which enables superior optical performance (particularly NIR responsivity) and an in-pixel stacking process to stack a SWIR photodiode on top on a regular visible (and/or NIR) light sensitive photodiode. A SWIR absorbing region (SiGe or Ge only) can be grown in Silicon by epitaxy. Floating diffusion and transfer gate from a first wafer (visible light sensing) can be accessed through a second wafer (SWIR wafer) so that both a SWIR and visible image can be captured simultaneously or sequentially. Visible (and NIR) photodiode may preserve a superior dark noise performance. The image sensor comprising the pixels described hereinafter can be operated as rolling shutter (RS), voltage domain or charge domain global shutter mode. Another aspect relates to a metalens which can be added between two wafers to focus incident light, such as light with SWIR wavelength, onto the pixels.

The terms VIS, NIR and SWIR denote electromagnetic radiation in the visual, near-infrared and short-wave infrared spectral range. VIS wavelengths range from 380 to 780 nm. The NIR region of the infrared spectrum is considered the wavelength range of 780 to 1400 nm. SWIR is the acronym for shortwave infrared and refers to non-visible light falling roughly between 1400 and 3000 nm in wavelength.

A three-dimensional integrated circuit (or 3D-IC) denotes an integrated circuit which is manufactured by stacking wafers, such as silicon wafers, or dies and interconnecting them vertically (e.g. with respect to a surface normal of the stack). For example, a 3D-IC is manufactured by stacking silicon wafers or dies and interconnecting them vertically using, for instance, by hybrid bonding, through-silicon vias (TSVs) or Cu—Cu connections using MOS (metal-oxide semiconductor) technology. The resulting 3D-IC behaves as a single device to achieve performance improvements at reduced power and smaller footprint than conventional two dimensional processes.

The terms top-tier, middle- and bottom-tier denote wafers or dies that are stacked to form the 3D IC. The orientation indicated by “top”, “middle” or “bottom” may be arbitrary and be subject to design choice. For example, the top-tier comprising the array of photodetectors may be top in the sense that, with respect to a surface normal of the stack, it is the tier that is arranged to receive incident light.

In at least one embodiment, an image sensor comprises a three-dimensional integrated circuit comprising a stack with at least a top-tier, a middle-tier, and a bottom-tier. The bottom-tier comprises a first array of photodetectors, denoted first pixels hereinafter. The first pixels are sensitive in the visual and/or near-infrared spectral range. The middle-tier comprises a second array of photodetectors, denoted second pixels hereinafter. The second pixels are sensitive in the short-wave infrared spectral range. The top-tier comprises an application-specific integrated circuit, denoted ASIC hereinafter, which is operable to read out the arrays of the first and second photodiodes, e.g. to form an image.

The proposed image sensor can image visible and short wave infrared wavelengths simultaneously or switch back and forth between said wavelengths as needed. A SWIR sensitive second pixel is stacked on visible light sensitive first pixel. The ASIC can read them separately or together. Visible light sensitive pixel can retain best dark noise performance in this arrangement. Advantages gained are the possibility of simultaneous VIS, NIR and SWIR imaging using same imaging device, maintain the same footprint, while using same readout circuitry and pipeline. The optical paths of VIS, NIR and/or SWIR imaging are common or same. All the three wavelength ranges (VIS, NIR and SWIR) share the same optical axis ensuring overlapping images from all three ranges.

In at least one embodiment, the top-tier, middle-tier, and bottom-tier are arranged in the stack to form a backside illuminated image sensor. Alternatively, the top-tier, middle-tier, and bottom-tier are arranged in the stack to form a front side illuminated image sensor. Front and backside illumination can be chosen to meet application requirements or design rules.

In at least one embodiment, the ASIC is operable to read out the pixels from the first and second array sequentially or in parallel. For example, the ASIC issues control signals to trunk transistor arrangements associated with the individual pixels to implement rolling shutter or global shutter readout, for example.

In at least one embodiment, trunk transistor arrangements to read out first and second pixels are distributed over the bottom-tier and the middle-tier. Alternatively, trunk transistor arrangements to read out first pixels are arranged in the bottom-tier and trunk transistor arrangements to read out second pixels are arranged in the middle-tier.

The trunk transistor arrangements, e.g. 3T cells, 4T cells or modifications thereof, constitute the circuitry to implement readout of pixels in the tiers. In this sense, the trunk transistor arrangements provide the circuitry and electrical connections for the ASIC to perform readout, e.g. according to a rolling shutter mode or global shutter mode.

In at least one embodiment, the trunk transistor arrangements under control of the ASIC are operable to operate according to a rolling shutter mode, according to a voltage domain global shutter mode or charge domain global shutter mode.

In at least one embodiment, at least one metalens is arranged in the stack between the bottom-tier and middle-tier. The metalens is operable to focus incident light from the short-wave infrared spectral range wavelength onto the second pixels from the second array. For example, there can be one metalens for each pixel (first or second).

In at least one embodiment, the metalens or lenses form a sub-wavelength lens and comprise a periodic or aperiodic pattern of semiconductor pillars. For example, the semiconductor pillars can be designed with different height, diameter and distance to each other, thus, providing a high degree of freedom for optical design of the lenses. The metalenses may increase the amount of incident, which can be detected by means of the second pixels, i.e. the SWIR sensitive pixels.

In at least one embodiment, pairs or groups of neighboring pillars form nano-antennae. The may comprise a dimer, i.e. two adjacent pillars, or a multimer of more adjacent pillars. These dimers or multimers form the nano-antennae and increase the degree of freedom for optical design even further.

In at least one embodiment, a first floating diffusion from the bottom-tier and a second floating diffusion of the middle-tier are electrically connected via vertical electrical connections to metal layers of the middle-tier to be accessed by the ASIC through the middle-tier. The vertical electrical connections facilitates parallel readout.

In at least one embodiment, the first pixels comprise a photodiode, e.g., a silicon based photodiode.

In at least one embodiment, the second pixels comprise a photodiode with a doped region, e.g. a p-SiGe or Ge region on a silicon based photodiode, for example. In addition, or alternatively, a quantum dot or stack of quantum dots can be used as second pixel.

In at least one embodiment, the image sensor further comprises at least one guard structure, e.g. a guard ring or a deep trench isolation, DTI. The guard structure is arranged in a substrate in the middle-tier and/or bottom-tier such as to surround the first and/or second pixels. The guard structure has the effect to optically isolate the pixels from neighboring pixels. This may increase the amount of incident light, which may be detected by a pixel and also reduce optical and electrical crosstalk to neighboring pixels.

In at least one embodiment, a filter layer comprising an array of optical filters is arranged on a substrate surface of the bottom-tier or the top-tier. In addition, or alternatively, a NIR structure is arranged on a substrate surface of the bottom-tier or the top-tier to scatter incident light. The filter layer and/or NIR structure can be arranged to alter the spectral content of light which is incident on the pixels, thus, allowing to implement a multispectral sensor or color image sensor.

In at least one embodiment, an electronic device comprises at least one image sensor according to one the aspects discussed above. A host system comprises the at least one image sensor. Host system may include a camera, mobile device, computer, an image sensor module, etc. The electronic device can be used as CMOS image sensor for a SWIR camera or multispectral imaging, for example.

Furthermore, a method of manufacturing an image sensor is suggested. The method comprises the step of stacking of at least a top-, a middle-, and a bottom-tier to form a three-dimensional integrated circuit. Another step involves arranging the bottom-tier with a first array of photodetectors, denoted first pixels, and the first pixels being sensitive in the visual and/or near-infrared spectral range. Another step involves arranging the middle-tier with a second array of photodetectors, denoted second pixels, and the second pixels being sensitive in the short-wave infrared spectral range. Another step involves arranging the top-tier with an application-specific integrated circuit, denoted ASIC, operable to read out the arrays of the first and second photodiodes.

Further embodiments of the method become apparent to the skilled reader from the aforementioned embodiments of the image sensor and of the electronic device, and vice-versa.

### BRIEF DESCRIPTION OF THE DRAWINGS

The following description of figures may further illustrate and explain aspects of the image sensor, electronic device and the method of manufacturing an image sensor. Components and parts of the self-mixing interferometry sensor that are functionally identical or have an identical effect are denoted by identical reference symbols. Identical or effectively identical components and parts might be described only with respect to the figures where they occur first. Their description is not necessarily repeated in successive figures.

In the figures:

FIG. 1 shows an example embodiment of an image sensor,

FIG. 2 shows an example of a voltage domain global shutter arrangement,

FIG. 3 shows an example of a rolling shutter arrangement,

FIG. 4 shows another example embodiment of an image sensor,

FIG. 5 shows another example of a rolling shutter arrangement,

FIG. 6 shows an example embodiment of an image sensor with a metalens,

FIG. 7 shows another example embodiment of an image sensor with a metalens,

FIG. 8 shows an example embodiment of an image sensor with front side illumination,

FIG. 9 shows another example embodiment of an image sensor with front side illumination,

FIGS. 10A, 10B show example embodiments of metalenses, and

FIGS. 11A, 11B show further example embodiments of metalenses.

### DETAILED DESCRIPTION

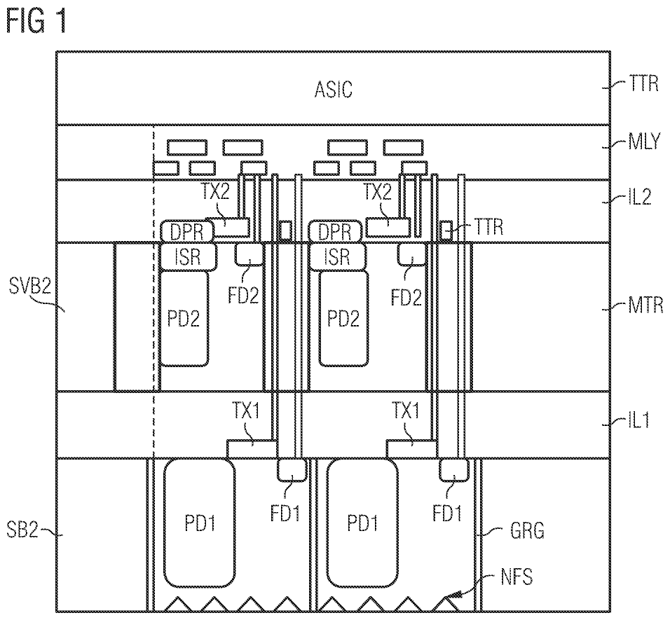

FIG. 1 shows an example embodiment of an image sensor. The image sensor comprises a three-dimensional integrated circuit comprising a stack with at least a top-tier TTR, a middle-tier MTR, and a bottom-tier BTR. In this example the top-, middle-, and bottom-tier are arranged in the stack to form a backside illuminated image sensor, i.e. incident light strikes the image sensor via the bottom-tier. The drawing shows two neighboring pixels from an array of such pixels, each comprising two sub-pixels PD1, PD2. The following discussion may focus on one pixel, which can be considered representative of other pixels, and, thus, the image sensor as a whole.

The bottom-tier BTR comprises a first substrate SB1, e.g. silicon. A first array of photodetectors is integrated into the first substrate. Hereinafter said photodetectors are denoted first sub-pixels, or first pixels for short. In the drawing two first pixels are shown. The first pixels are implemented as photodiodes, e.g. silicon based photodiodes. The first pixels are sensitive to incident from the visual, VIS, and/or near-infrared, NIR, spectral range.

Furthermore, a first floating diffusion FD1, also called “sense node”, is arranged in the first substrate SB1, e.g. by a pn-junction, and electrically isolated from other nodes. The floating diffusion FD1 is arranged to store charge and is represented by a first capacitance Cfd1.

Optionally, an NIR filter structure NFS is arranged on or in the first substrate. The NIR filter structure is designed so that incident NIR light can pass towards or is blocked from reaching the first pixels. The NIR filter structure may only be arranged in front of every other pixel, as part of a color cell, for example. For example, the NIR filter structure comprises scattering structures of semiconductor material such as pyramids, which scatter the incident light depending on their wavelength.

Optionally, a guard structure GRG, e.g. a guard ring and/or a deep trench isolation, DTI is arranged in the first substrate SB1. The guard structure optically isolates neighboring first pixels PD1 from one another. This way incident light is guided towards pixels in the bottom-tier BTR and further towards the middle-tier MTR. The guard structure GRG can be made from Tungsten, Silicon, Oxide or polysilicon, for example.

A first intermediate layer IL1 is arranged between the bottom-tier BTR and the middle-tier MTR. The first intermediate layer IL1 can be considered as part of the bottom-tier BTR and can be based on an oxide, such as silicon oxide. In this example, a first transfer gate TX1 is arranged in the first intermediate layer IL1. For example, the transfer gate TX1, is introduced between the first pixel PD1 and the floating diffusion FD1. The transfer gate TX1 is operable to transfer charge onto the sense node FD1.

The middle-tier MTR is arranged on the bottom-tier BTR, with the first intermediate layer IL1 in-between. The middle-tier MTR comprises a second substrate SB2, e.g. silicon. A second array of photodetectors is integrated into the second substrate SB2. The photodetectors are denoted second sub-pixels, hereinafter, or second pixels PD2 for short. The second pixels PD2 are sensitive in the short-wave infrared spectral range. In the drawing two second pixels PD2 are shown. The second pixels are implemented as photodiodes. For example, the second pixels comprise a doped region DPR, e.g. are arranged as p-SiGe or Ge on silicon based photodiodes. The doped region DPR features an absorption band in the short-wave infrared spectral range. Furthermore, a second floating diffusion FD2, or “sense node”, is arranged in the second substrate SB2, e.g. by a pn-junction, and electrically isolated from other nodes. The doped region DPR, e.g. SiGe layer, can be deposited on a surface of the second substrate SB2, such as Silicon, or embedded deep in the second substrate. The floating diffusion FD2 is arranged to store charge and is represented by a second capacitance Cfd2.

A second intermediate layer IL2 is arranged between the middle-tier MTR and the top-tier TTR. The second intermediate layer IL2 can be considered as part of the middle-tier MTR and can be based on an oxide, such as silicon oxide. In this example, a second transfer gate TX2 is arranged in the second intermediate layer IL2. For example, the transfer gate TX2, is introduced between the pixel and the floating diffusion FD2. The transfer gate TX2 is operable to transfer charge onto the sense node FD2. Furthermore, an intrinsic semiconductor region ISR, e.g. of i-SiGe, is arranged between the second pixel PD2 and the second transfer gate TX2. The intrinsic semiconductor region ISR, i-SiGe, is arranged below the doped region DPR, p-SiGe. The doped region DPR is optional. The intrinsic semiconductor region ISR can be arranged on top or below the second pixel PD2. Furthermore, trunk transistors TRT are arranged in the intermediate layer as will be discussed further below.

A metal layer MLY is arranged between the second intermediate layer IL2 and the top-tier TTR. The metal layer MLY comprises a number metal layers which establish electrical connections between the tiers. For example, metal layers are electrically connected to the first and second floating diffusions FD1, FD2 and to the first and second transfer gates TX1, TX2, respectively. The electrical connections are established by vertical electrical connections that pass through the metal layer MLY and, in part, through the second substrate SB2 of the middle-tier MTR. For example, an oxide region OXR is arranged in the second substrate and the vertical electrical connections pass through said oxide region to the first intermediate layer IL1 and bottom-tier BTR. In this example, the first and second floating diffusion FD1, FD2 is electrically interconnected by means of a vertical electrical connection. Furthermore, the first transfer gate TX1 in the bottom-tier BTR can be accessed from the middle-tier MTR, i.e. the metal layer MLY on the middle-tier MTR.

Furthermore, the top-tier TTR is arranged on the middle-tier MTR, with the second intermediate layer IL2 in-between. The top-tier TTR comprises an application-specific integrated circuit, denoted ASIC, which controls operation of the image sensor. For example, the ASIC controls read out the pixels PD1, PD2 of the arrays. Operation will be discussed in more detail with respect to the following figures.

Basically, in operation the image sensor is exposed to incident light, which may have contribution from VIS, NIR and SWIR (e.g., at 1550 nm). The incident light strikes the image sensor via the bottom-tier BTR. The light is scattered at the NIR filter structure NFS and eventually is coupled into the first substrate SB1. Light may travel through the first substrate SB1 and towards the first pixels PD1, where VIS and NIR components may be absorbed. Charge can be temporally saved in the floating diffusion FD1 and read out by way of the transfer gate TX1, when acquisition of an image has terminated. Light may travel further into the middle-tier MTR and along the second substrate SB2 towards the second pixels PD2, where SWIR components may be absorbed, e.g. by way of the doped region DPR. Charge can be temporally saved in the floating diffusion FD2 and read out by way of the transfer gate TX2, when acquisition of an image has terminated.

For example, dark current (DC) can be optimized for a Silicon only photodiode where as SWIR photodiode (due to SiGe integration) dark current is usually couple of order higher. SiGe on Si creates a interface that may have many defects which generates dark current (DC).

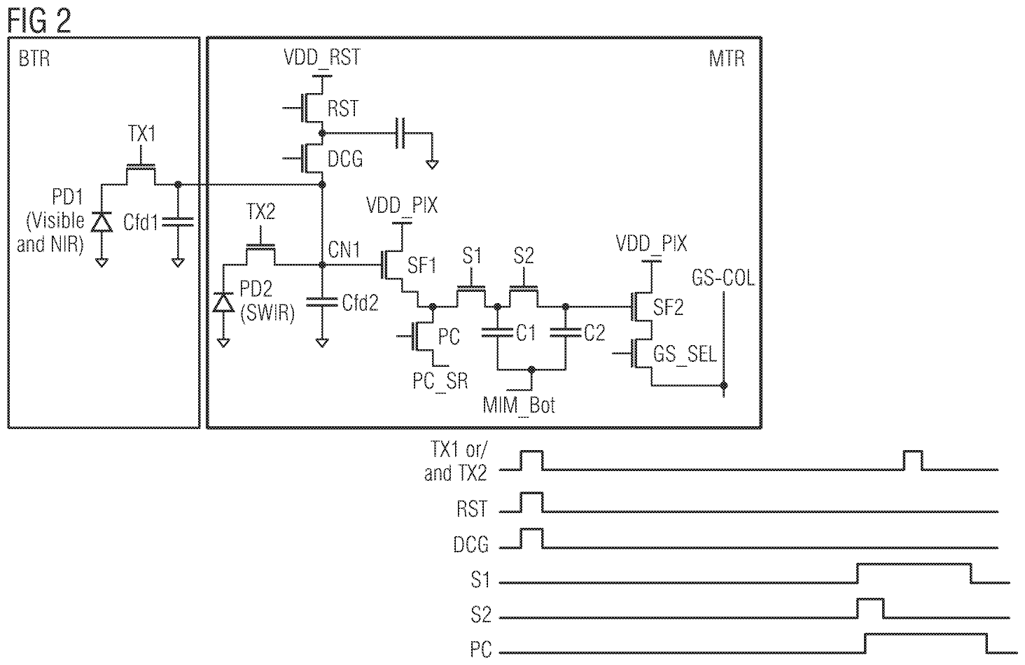

FIG. 2 shows an example of a voltage domain global shutter arrangement. The circuit layout shows one possible arrangement to control the image sensor of FIG. 1. As already discussed, the first pixel PD1 (visible and NIR) and first transfer gate TX1 are located in the bottom-tier BTR. Similarly, the second pixel PD2 (SWIR) and second transfer gate TX2 are located in the middle-tier MTR. The first and second floating diffusion FD1, FD2 (as represented by capacitances Cfd1 and Cfd2) are electrically interconnected by means of a vertical electrical connection via a first circuit node CN1. The further circuitry resembles a known voltage domain global shutter circuitry comprising trunk transistors TTR arranged as a modified 4T cell.

The modified 4T cell comprises CMOS (complementary metal-oxide-semiconductor) trunk transistors, including the two transfer gates TX1, TX2, a reset gate RST, a dual conversion gate DCG, a selection gate GS_SEL and two source-follower readout transistors SF1, SF2. The reset gate RST and dual conversion gate DCG are interconnected in one branch to the circuit node CN1, which is further connected to the first source-follower readout transistor SF1. The first and second source-follower readout transistors SF1, SF2 are interconnected via transistors PC, S1 and S2. The timing diagram shows example sequencing of control signals (indicated by the reference numerals of the corresponding trunk transistors and being applied to their respective control sides, e.g. gates). The voltage domain global shutter arrangement is shared over two tiers, i.e. bottom- and middle-tier. The pixels PD1, PD2 can be read out sequentially one after another or in parallel two at a time.

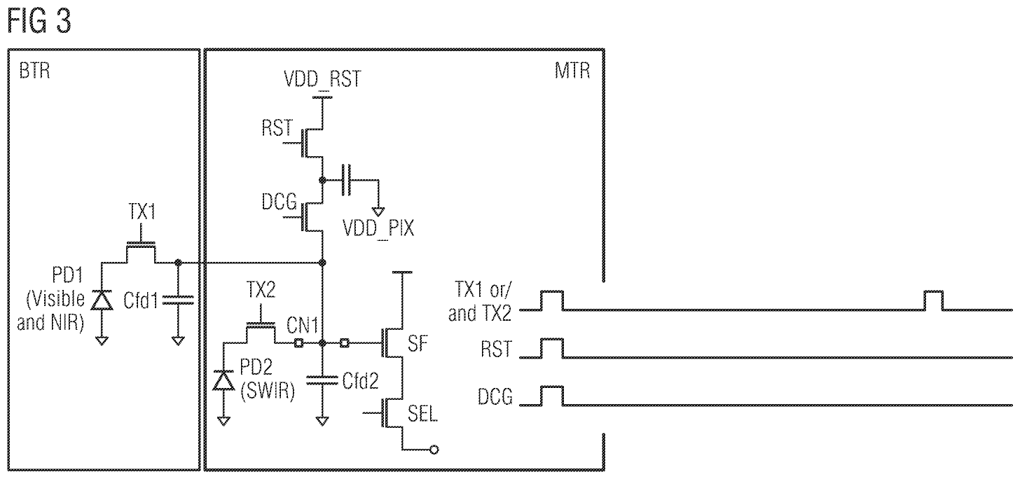

FIG. 3 shows an example of a rolling shutter arrangement. The circuit layout shows another possible arrangement to control the image sensor of FIG. 1. The circuit only differs in a modified 4T cell. This layout comprises only one source-follower readout transistors SF connected to the circuit node CN1 and selection gate SEL. The timing diagram shows example sequencing of control signals (indicated by the reference numerals of the corresponding trunk transistors and being applied to their respective control sides, e.g. gates). The rolling shutter arrangement is shared over two tiers, i.e. bottom- and middle-tier. The pixels PD1, PD2 can be read out sequentially one after another or in parallel two at a time.

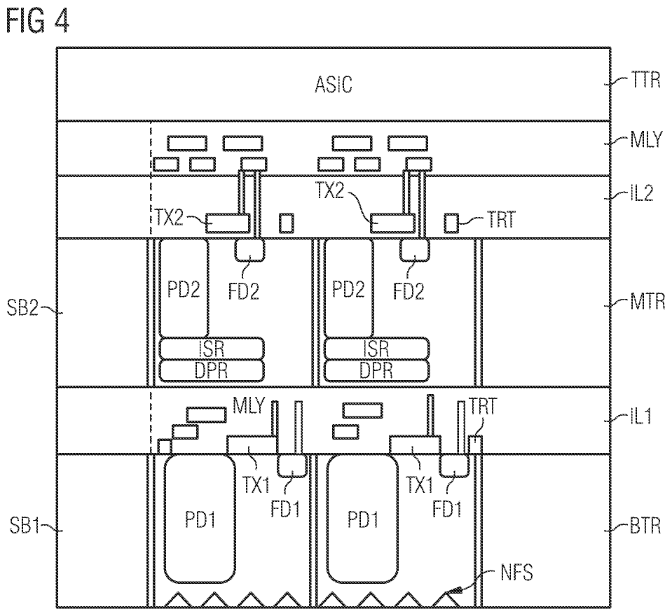

FIG. 4 shows another example embodiment of an image sensor. This embodiment is based on the one shown in FIG. 1. It has two major differences, which can be implemented together in one embodiment as shown, or only one of the two may be implemented. First, the doped region DPR, e.g. p-SeGe, and the intrinsic semiconductor region ISR, e.g. of i-SiGe, arranged of the middle-tier MTR are arranged in the second substrate SB2 or a surface of the second substrate SB2 below (as seen from the bottom-tier BTR) the second pixel PD2. Second, there are separate trunk transistors TTR, e.g. arranged as a voltage domain global shutter arrangement or as a rolling shutter arrangement, in or on the middle-tier MTR but also the bottom-tier BTR. In this embodiment, another metal layer MLY is arranged between the first intermediate layer IL1 and the middle-tier MTR. The metal layer MLY comprises layers of metal which establish electrical connections between the tiers. In a certain sense the first pixels PD1 have their trunk transistors TTR and metal layers MLY. The ASIC can be shared with a column level hybrid bond, for example.

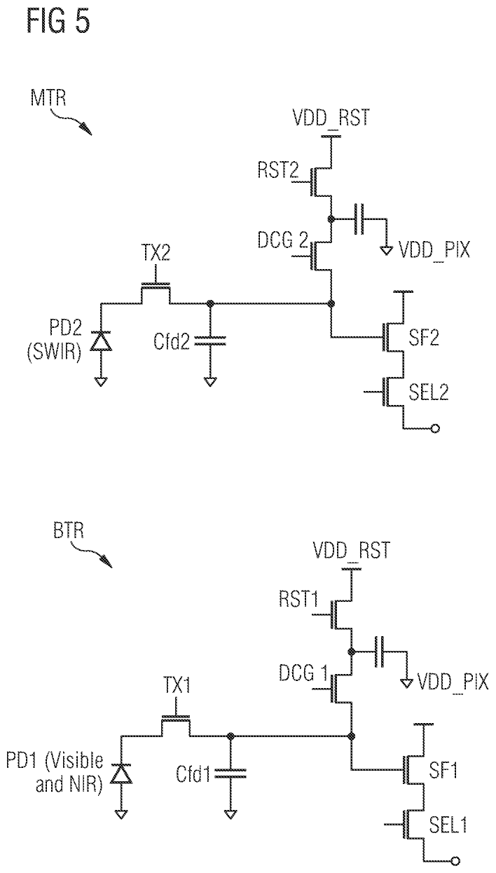

FIG. 5 shows another example of a rolling shutter arrangement. The circuit layout shows two of the stacked pixels PD1, PD2 (pinned photodiodes) with their respective floating diffusions FD1, FD2 represented by capacitances Cfd1, Cfd2, and trunk resistors TTR arranged in a modified 4T cell comprising CMOS transistors: transfer gates TX1, TX2, reset gates RST1, RST2, selection gate, dual conversion gates DCG1, DCG2, source-follower readout transistors SF1, SF2 as well as selection gates SEL1, SEL2. The timing or sequencing of control signals can applied according to a rolling shutter scheme. This way, each tier has its own rolling shutter arrangement. The pixels PD1, PD2 can be read out sequentially one after another or in parallel two at a time.

In another embodiment (not shown) each tier BTR, MTR comprises a respective global shutter arrangement with modified 4T cells arranged in each tier for the pixels arranged therein.

A metalens MLS can be added between one and/or two of the tiers to focus light better into a respective photodetector. A metalens can be made of pillars PLS of semiconductor material, such as Silicon or other high index materials such as Silicon Nitride, Titanium dioxide. For example, light exiting from the first substrate SB1 into the first interlayer IL1 (e.g., oxide) typically is angle limited, e.g. some 25 degrees (assuming Si to SiO₂ interface). This limits range of incidence angles for the metalens MLS. For example, the metalens is designed to focus SWIR light onto the second pixels after exiting the first substrate SB1 or a first pixel PD1. The doped region DPR, e.g. SiGe layer, can be deposited on a surface of the second substrate SB2, such as Silicon, or embedded deep in the second substrate. The position and focusing power (design) of metalens MLS can be chosen accordingly.

The metalens MLS can be etched into the substrate, e.g. the first or second substrate SB1, SB2, or formed in an intermediate layer IL1, IL2 or another layer, such as a Silicon layer grown on SiO₂. The metalens MLS typically is complemented with the guard structure GRG, e.g. the first pixels to prevent SWIR light from pixel leaking into neighboring pixel and causing cross-talk. Due to limited lateral size of the second pixels PD2 (can be same lateral size as the first pixels or integer multiples) a metalens MLS will be of limited lateral size.

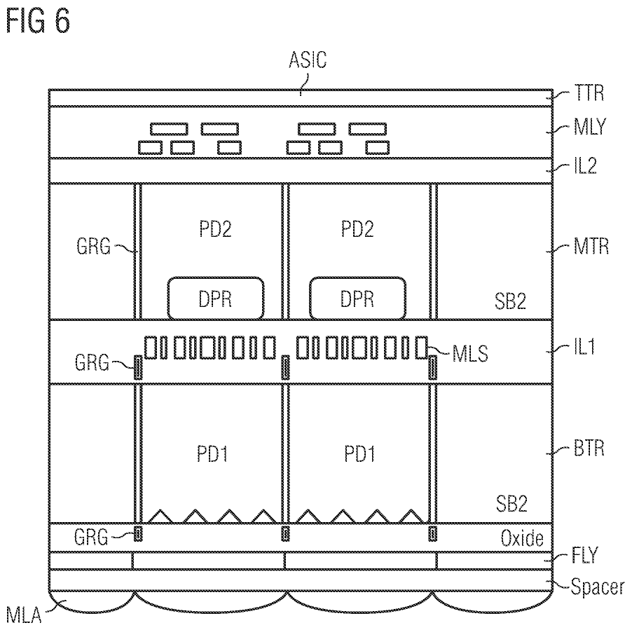

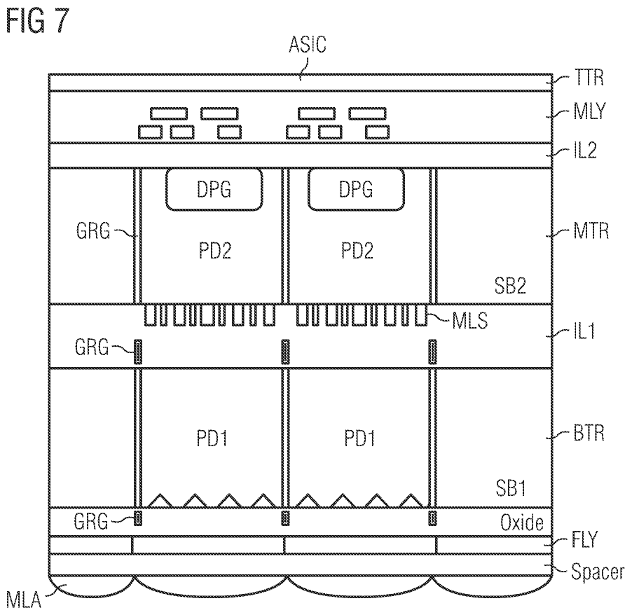

FIG. 6 shows an example embodiment of an image sensor with a metalens. This example shows a modified image sensor based on the example of FIG. 4. In addition, a metalens MLS is arranged in the first intermediate layer IL1 (oxide) between the bottom- and middle-tier BTR, MTR. The metalens MLS is arranged to focus light onto the second pixels PD2, e.g. the doped regions DPR. FIG. 7 shows another example embodiment of an image sensor with a metalens. This example shows a modified image sensor based on the example of FIG. 1. In addition, a metalens is arranged in the first intermediate layer IL1 (oxide) between the bottom- and middle-tier BTR, MTR but etched into the second substrate SB2.

FIGS. 6 and 7 further show that guard structures GRG are arranged around both first and second pixels PD1, PD2, i.e. arranged in the first and second substrate SB1, SB2. The rings can be made from Tungsten (BSME).

Furthermore, optionally both FIGS. 6 and 7 show a filter layer FLY, which can be arranged on an outer surface of the bottom-tier BTR, for example. The filter layer FLY can be arranged on top of the NIR filter structure NFS, or instead of said structure. In this example, the filter layer FLY comprises a respective pattern of single optical filters OPF to form color cells. For example, there may be a red, green, blue and NIR color filter arranged in front of respective first pixels to form RGB-NIR sensitive pixels. Furthermore, a microlens array MLA may be arranged on the filter layer FLY (e.g., spaced away by means of spacer layer) to further focus light into the pixels of the image sensor.

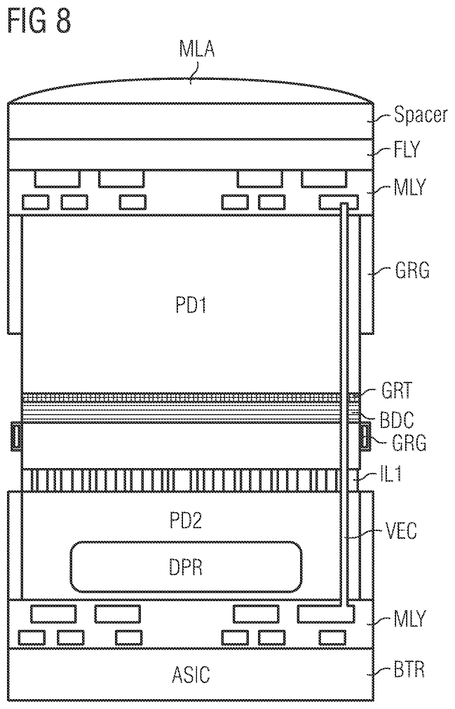

FIG. 8 shows an example embodiment of an image sensor with front side illumination. The drawing shows a single pixel with the first and second pixels as sub-pixels PD1, PD2. In this design, the bottom- and top-tiers BTR, TTR are switched so that the ASIC is arranged in the bottom-tier BTR and the first pixel PD1 is arranged in the top-tier TTR. Light is incident on the image sensor from the top.

The stack comprises (in this order): The bottom-tier BTR, a first intermediate layer IL1 with metal layers MLY, the middle-tier MTR comprising the second pixel PD2 with a doped region DPR and modified 4T cell surrounded by a guard structure GGR. Furthermore, in the stack a second intermediate layer IL2 (oxide) is arranged between the bottom- and middle-tier BTR, MTR. This layer IL2 encloses a metalens MLS, which in this example is etched into the substrate SB1 of the bottom-tier BTR. The second intermediate layer IL2 is surrounded by another guard structure GGR to improve modulation transfer function (MTF) for SWIR light and reduce optical crosstalk to neighboring pixels. As an option, the second intermediate layer IL2 is covered with a dielectric Bragg Dichroic Reflector BDR, which transmits SWIR but reflects VIS and NIR. As a further option, a grating GRT (e.g., for NIR) can be etched into a surface of the substrate SB2 of the top-tier TTR. The top-tier comprises the first pixel PD1 and modified 4T cell surrounded by a guard structure GGR. A second intermediate layer IL2 is arranged on the top-tier TTR and comprises metal layers MLY which provide vertical electrical connections to the ASIC.

A filter layer FLY is arranged on an outer surface of the top-tier TTR. In this example, the filter layer comprises a filter to form part of a color cell. For example, the filter may be a red, green, blue and NIR color filter arranged in front of respective first pixels PD1 to form part of a RGB-NIR sensitive pixels. Furthermore, a microlens array MLA may be arranged on the filter layer FLY (e.g., spaced away by means of spacer layer) to further focus light into the pixels of the image sensor.

Manufacture steps may include attaching top-tier or wafer to a carrier wafer while SWIR fab steps are carried out. The microlens array can be attached after the bottom-tier with the ASIC (carrier) wafer has been attached. Silicon in the bottom-tier can be grown by using CVD techniques as used in manufacture of SOI wafers.

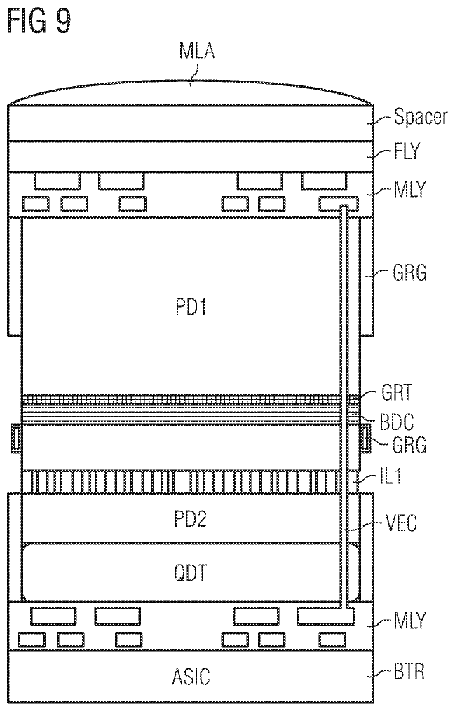

FIG. 9 shows another example embodiment of an image sensor with front side illumination. This example is based on the one discussed with respect to FIG. 8. However, the second pixels PD2, which is sensitive to SWIR is exchanged with a stack of quantum dots QDT. The stack of quantum dots are arranged so as to absorb light from the SWIR spectral range. Said quantum dots can also be used to in exchange for second pixels in the other examples discussed above.

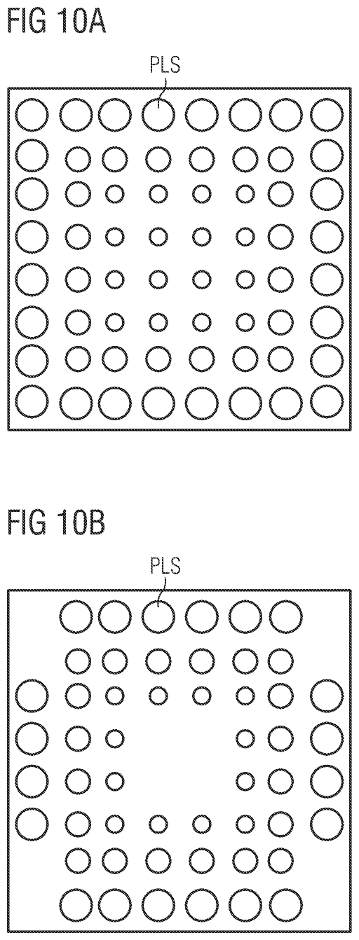

FIGS. 10A and 10B show example embodiments of metalenses. FIG. 10A shows a design which fills all space in a rectangular grid to improve focus efficiency. The metalens comprises groups of pillars with same diameters and arranged in periodic or aperiodic patterns.

The metalens discussed above with respect to various example embodiments comprises pillars of substrate material, e.g. Silicon, which are arranged in a periodic or aperiodic fashion. The metalens may form a sub-wavelength lens. The height of pillars PLS can range from 500 nm to 1000 nm (based on design). The diameters of pillars can vary from 50 nm to 500 nm. In case of a metalens implemented as a periodic array of pillars, the periodicity can vary from 200 nm to 600 nm (a periodicity value is dependent on first and second pixel sizes and hence design dependent).

The distance of the pillar PLS to an edge of a second pixel typically is decided by design rules and metalens pillars need to be optimized with this constraint to increase the quantum efficiency of a second pixel. The metalens MLS can also be created by arranging nano-antenna (made up of two pillars) in periodic or aperiodic manner. In this case, the focus of the lens may be adjusted by spatially varying the diameters or the pillars PLS and spacing's between them. An example of nano-antenna can be dimer structure—two pillars with different diameters each with an angle of deflection adjusted by varying spacing between the pillars and/or the pillar diameters.

FIGS. 10A and 10B show example embodiments of metalenses. FIG. 10A shows a design which fills all space in a rectangular grid to improve focus efficiency. The metalens comprises groups of pillars of same diameters, which are arranged in concentric rectangles. A first group having a square shaped is located at a center. 4×4 pillars are shown as an example and have a same first diameter. Said square is surrounded and centered by a second group of pillars of a second same diameter. These pillars encompass those of the first group in a single contiguous layer. Finally, a third group of pillars of a third same diameter surrounds and is centered to the second group of pillars. These pillars encompass those of the second group in another single contiguous layer. FIG. 10B shows a modified design, where in contrast to FIG. 10A parts of the grid, e.g. a central part, are not filled with pillars to increase transmission efficiency.

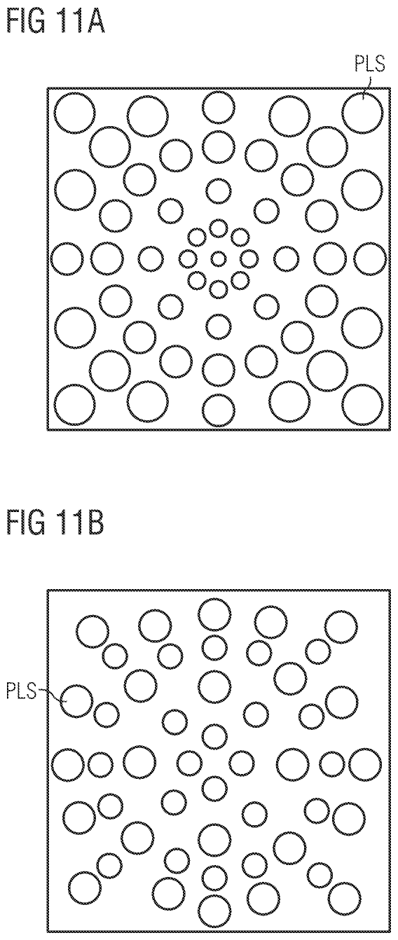

FIGS. 11A and 11B show further example embodiments of a metalens. The example of FIG. 11A is similar to that of FIG. 10A but with circular groups of pillar rather than rectangular. This design too fills the substrate space using circular symmetry to create the metalens. The example of FIG. 11B comprises pairs or dimers of pillars, which form nano-antennae. These pairs can be arranged in a periodic or aperiodic fashion, e.g. centered on a common center point. Periodic/aperiodic arrangement of nano-antennae (in this case a dimer consisting comprising two pillars with different diameters). The dimers can be arranged in rectangular or circular symmetry.

In general, the design of metalenses is not restricted to the examples discussed herein. Typically, an actual metalens design may be the result of simulations using dedicated optical design software. Thus, any metalens design may be tailored to a desired application and optical properties demanded thereby.

The above presented improved concept in the field of image sensors allows for simultaneous imaging of VIS, NIR and SWIR spectral ranges using the same device (using same footprint, and readout circuitry) and using same optical path/optical axis can be very valuable to many applications such as artificial and virtual reality (AR/VR), consumer, health, security, robotics, etc.

The improved concept enables both Visible and SWIR imaging on same chip, foot print. Images can be captured together of sequentially. All wavelength ranges (VIS, NIR and SWIR) share the same optical path/optical axis. This allows for images to be pre-aligned and overlapped optically without need for software image registration/overlap.

The improved concept discloses an imaging device that can image visible and SWIR (Short Wave Infra-Red) wavelength simultaneously or switch back and forth between them as needed. SWIR sensitive pixel is stacked on Visible light sensitive pixel, then ASIC can read them separately or together. Visible light sensitive pixel can retain best dark noise performance in this arrangement.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous.

Features recited in separate dependent claims may be advantageously combined. Moreover, reference signs used in the claims are not limited to be construed as limiting the scope of the claims.

Furthermore, as used herein, the term “comprising” does not exclude other elements. In addition, as used herein, the article “a” is intended to include one or more than one component or element, and is not limited to be construed as meaning only one.

### REFERENCES

BTR bottom-tier
Cfd1 capacitance
Cfd2 capacitance
CN1 circuit node
BDR dielectric Bragg Dichroic Reflector
DCG dual conversion gate
DCG1 dual conversion gate
DCG2 dual conversion gate
DPR doped region
FD1 floating diffusion
FD2 floating diffusion
FLY filter layer
GRG guard structure
GRT grating
GS_SEL selection gate
IL1 intermediate layer
IL2 intermediate layer
ISR intrinsic semiconductor region
MLA microlens array
MLS metalens
MLY metal layer
MTR middle-tier
NFS NIR filter structure
OPF optical filters
OXR oxide region
PC transistor
PD1 first (sub-)pixel
PD2 second (sub-)pixel
QDT stack of quantum dots
PLS pillar
RST reset gate
RST1 reset gate
RST2 reset gate
S1 transistor
S2 transistor
SB1 substrate
SB2 substrate
SEL selection gate
SEL1 selection gate
SEL2 selection gate
SF source-follower readout transistor
SF1 source-follower readout transistor
SF2 source-follower readout transistor
TRT trunk transistors
TTR top-tier
TX1 transfer gate
TX2 transfer gate

1. An image sensor, comprising a three-dimensional integrated circuit comprising a stack with at least a top-, a middle-, and a bottom-tier, wherein:
the bottom-tier (BTR) comprises a first array of photodetectors, denoted first pixels (PD1), the first pixels being sensitive in the visual and/or near-infrared spectral range,
the middle-tier (MTR) comprises a second array of photodetectors, denoted second pixels (PD2), the second pixels being sensitive in the short-wave infrared spectral range, and
the top-tier (TTR) comprises an application-specific integrated circuit, denoted ASIC, operable to read out the arrays of the first and second photodiodes (PD1, PD2).

2. The image sensor according to claim 1, wherein:
the top-tier (TTR), middle-tier (MTR), and bottom-tier (BTR) are arranged in the stack to form a backside illuminated image sensor, or
the top-tier (TTR), middle-tier (MTR), and bottom-tier (BTR) are arranged in the stack to form a front side illuminated image sensor.

3. The image sensor according to claim 1, wherein the ASIC is operable to read out the pixels from the first and second array sequentially or in parallel.

4. The image sensor according to claim 1, wherein
trunk transistor arrangements to read out first and second pixels (PD1, PD2) are distributed over the bottom-tier (BTR) and the middle-tier (MTR), or
trunk transistor arrangements to read out first pixels (PD1) are arranged in the bottom-tier (BTR) and trunk transistor arrangements to read out second pixels (PD2) are arranged in the middle-tier (MTR).

5. The image sensor according to claim 1, wherein the trunk transistor arrangements under control of the ASIC are operable to operate according to a rolling shutter mode, according to a voltage domain global shutter mode or charge domain global shutter mode.

6. The image sensor according to claim 1, wherein
a metalens (MLS) is arranged in the stack between the bottom-tier (BTR) and middle-tier (MTR) and
the metalens (MLS) is operable to focus incident light from the short-wave infrared spectral range wavelength onto the second pixels (PD2) from the second array.

7. The image sensor according to claim 6, wherein the metalens (MLS) forms a sub-wavelength lens and comprises a periodic or aperiodic pattern of semiconductor pillars (PIL).

8. The image sensor according to according to claim 7, wherein pairs or groups of neighboring pillars (PIL) form nano-antennae.

9. The image sensor according to claim 1, wherein:
a first floating diffusion (FD1) and a first transfer gate (TX1) from the bottom-tier (BTR) are electrically connected via vertical electrical connections to metal layers (MLS) of the middle-tier (MTR) to be accessed by the ASIC through the middle-tier (MTR).

10. The image sensor according to claim 1, wherein the first pixels (PD1) comprise a photodiode, e.g., a silicon based photodiode.

11. The image sensor according to claim 1, wherein the second pixels (PD2) comprise:
a photodiode with a doped region, e.g. a p-SiGe or Ge region on a silicon based photodiode, and/or
a quantum dot or stack of quantum dots.

12. The image sensor according to claim 1, further comprising at least one guard structure arranged in a substrate around the first and/or second pixels (PD1, PD2).

13. The image sensor according to claim 1, comprising:
a filter layer (FLR) comprising an array of optical filters (OFS), arranged on a substrate surface of the bottom-tier (BTR) or the top-tier (TTR), and/or
a NIR structure (NSE) arranged to scatter incident light arranged on a substrate surface of the bottom-tier (BTR) or the top-tier (TTR).

14. An electronic device comprising:
at least one image sensor according to claim 1, and
a host system comprising the at least one image sensor.

15. A method of manufacturing an image sensor, the method comprising:
stacking of at least a top-, a middle-, and a bottom-tier to form a three-dimensional integrated circuit,
arranging the bottom-tier (BTR) with a first array of photodetectors, denoted first pixels (PD1), the first pixels being sensitive in the visual and/or near-infrared spectral range,
arranging the middle-tier (MTR) with a second array of photodetectors, denoted second pixels (PD2), the second pixels being sensitive in the short-wave infrared spectral range, and
arranging the top-tier (TTR) with an application-specific integrated circuit, denoted ASIC, operable to read out the arrays of the first and second photodiodes (PD1, PD2).
